(19) United States
(12) Patent Application Publication
(10) Pub. No.: US 2022/0013382 A1
(43) Pub. Date: Jan. 13, 2022

(54) TRANSFER CAROUSEL WITH DETACHABLE CHUCKS

(71) Applicant: Applied Materials, Inc., Santa Clara, CA (US)

(72) Inventors: Bhaskar PRASAD, Adityapur (IN); Kirankumar Neelasandra SAVANDAIAH, Bangalore (IN); Srinivasa Rao YEDLA, Bangalore (IN); Nitin Bharadwaj SATYAVOLU, Kakinada (IN); Thomas BREZOCZKY, Los Gatos, CA (US)

(21) Appl. No.: 16/924,636

(22) Filed: Jul. 9, 2020

(51) Int. Cl. H01L 21/67; B65G 47/90; H01L 21/687

(52) U.S. Cl. CPC H01L 21/67167; H01L 21/68707; B65G 47/907

(57) ABSTRACT

A transfer apparatus for use in a multiple processing region system is disclosed that includes a carousel that includes a hub having a plurality of transfer arms extending therefrom. Each of the transfer arms include a first end coupled to the hub and a second end, the second end comprising a component supporting region, and a plurality of electrical interface connections distributed about the component supporting region.

### BACKGROUND

### Field

Embodiments of the present disclosure generally relate to methods and apparatus for processing substrates. More particularly, embodiments of the disclosure relate to substrate processing platforms, which use multiple processing chambers for processing substrates.

### Description of the Related Art

The present disclosure relates to a method and an apparatus for the processing of substrates in a vacuum, i.e., in a sub-atmospheric pressure environment. More particularly, the present disclosure relates to the deposition of thin films on a substrate in a vacuum environment, the removal of all or a portion of a thin film from a substrate in a vacuum environment, or the performance of other processes on a substrate in a vacuum environment.

Conventional cluster tools are configured to perform one or more processes during substrate processing. For example, a cluster tool can include a physical vapor deposition (PVD) chamber for performing a PVD process on a substrate, an atomic layer deposition (ALD) chamber for performing an ALD process on a substrate, a chemical vapor deposition (CVD) chamber for performing a CVD process on a substrate, and/or one or more other processing chambers.

Many thin film deposition and etch processes used in semiconductor and flat panel display production employ single substrate processing chambers, wherein a single substrate is loaded into a dedicated vacuum process chamber having dedicated hardware therein to support the substrate during a process performed thereon. The time required to load the substrate into the chamber, electrostatically chuck the substrate to a substrate support, dechuck the substrate, and unload the substrate from the chamber adds to the total time required to process a substrate in a process chamber.

The aforementioned conventional apparatus configurations have limitations, such as mechanical throughput, processing environment contamination, and process flexibility. Therefore, what is needed in the art is a transfer apparatus for the cluster tool capable of improving the mechanical throughput, process cleanliness, and increasing process flexibility.

### SUMMARY

In one embodiment, a transfer apparatus for use in a multiple processing region system is disclosed that includes a carousel that includes a hub having a plurality of transfer arms extending therefrom. Each of the transfer arms include a first end coupled to the hub and a second end, the second end comprising a component supporting region, and a plurality of electrical interface connections distributed about the component supporting region.

In another embodiment, a transfer apparatus for use in a multiple processing region system is disclosed that includes a carousel that includes a hub having a plurality of transfer arms extending therefrom. Each of the transfer arms include a first end and a second end, the second end comprising a fork, and a plurality of electrical interface connections distributed about the fork and protruding from a surface thereof. Each of the plurality of transfer arms includes a feature formed therein for receiving a plurality of electrical wires positioned between the hub and the electrical interface connections. In some embodiments, the feature formed in each of the transfer arms is a through-hole and/or a channel formed in a surface of the transfer arm.

In another embodiment, an apparatus for substrate processing is disclosed which includes a plurality of processing chambers coupled to a central transfer chamber. The central transfer chamber comprises a carousel that includes a hub having a plurality of transfer arms extending therefrom at an angle relative to a rotational axis of the carousel. Each of the transfer arms include a first end and a second end, and a plurality of electrical interface connections that are distributed about the second end. In some embodiments, the second end comprises a fork.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a plan view of a processing module according to one embodiment.

FIG. 2A is a perspective view of one embodiment of a carousel that may be used in the central transfer apparatus of FIG. 1.

FIG. 2B is a schematic perspective view of a portion of one of the transfer arms of the carousel of FIG. 2A.

FIG. 2C is a schematic side view of a portion of the hub of the carousel and a transfer arm mounted thereto.

FIG. 2D is a plan view of one embodiment of a carousel that may be used in the central transfer apparatus of FIG. 1.

FIG. 2E is a plan view of one embodiment of a carousel that may be used in the central transfer apparatus of FIG. 1.

FIG. 3 is a schematic sectional side view of a portion of one of the transfer arms of the carousel of FIG. 2A.

FIG. 4A is a schematic sectional perspective view of a shaft assembly for the carousel, according to one embodiment.

FIG. 4B is a schematic illustration of an electrical circuit formed when a chuck assembly is positioned on a transfer arm of a carousel, according to one embodiment.

FIG. 5A is a top plan view of a heat shield assembly that may be utilized with the transfer arms as described herein.

FIGS. 5B-5D are side views of portions of the heat shield assembly shown in FIG. 5A.

FIG. 5E is a side sectional view of the heat shield assembly, the chuck assembly, and a portion of a transfer arm.

FIG. 6 is a plan view of a transfer arm assembly according to an embodiment.

FIG. 7 is an isometric view of a processing module according to another embodiment.

FIG. 8 is a side cross-sectional view of the processing module formed along lines 8-8 in FIG. 7.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the apparatus and methods, it is to be understood that the disclosure is not limited to the details of construction or process steps set forth in the following description. It is envisioned that some embodiments of the present disclosure may be combined with other embodiments.

One or more embodiments of the present disclosure are directed towards apparatus for substrate processing and a cluster tool including a transfer apparatus and a plurality of processing stations. In some embodiments, the transfer apparatus is configured as a carousel, and the processing stations may include facilities to enable atomic layer deposition (ALD), chemical vapor deposition (CVD), physical vapor deposition (PVD), etching, cleaning, thermal processing, annealing, and/or polishing processes. Other processing platforms may also be used with the present disclosure at the discretion of a user. The present disclosure generally includes a substrate processing tool that has a high throughput, increased adaptability, and a smaller footprint than conventional cluster tools.

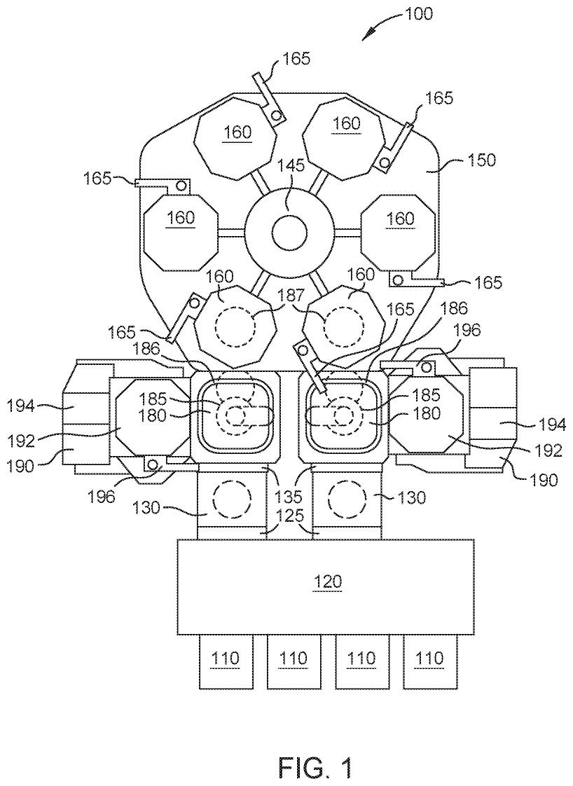

FIG. 1 is a plan view of one embodiment of a processing module 100. The processing module 100 includes a plurality of Front Opening Unified Pods (FOUPs) 110, a Factory Interface (FI) 120 adjacent to the FOUPs 110, a plurality of load lock chambers 130 adjacent to the FI 120, a plurality of robot chambers 180 adjacent to the plurality of load lock chambers 130, a plurality of preparation chambers 190 adjacent to the plurality of robot chambers 180, and a transfer chamber assembly 150 adjacent to the plurality of robot chambers 180.

The plurality of FOUPs 110 may be utilized to safely secure and store substrates between movement from different machines. The plurality of FOUPs 110 may vary in quantity depending upon the process and throughput of the system. The FI 120 is disposed between the plurality of FOUPs 110 and the plurality of load lock chambers 130. The FI 120 creates an interface between the factory and the remainder of the processing module 100. The plurality of load lock chambers 130 are connected to the FI 120 by first slit valves 125 (e.g., gate valves), such that a substrate may be transferred from the FI 120 to the plurality of load lock chambers 130 through the first slit valves 125 and from the plurality of load lock chambers 130 to the FI 120. The first slit valves 125 may be on one wall of the load lock chambers 130. In some embodiments, the first slit valves 125 may be fluid isolation valves and may form a seal between the FI 120 and the load lock chambers 130. This seal may keep outside contaminants from entering the processing module 100. The load lock chambers 130 also comprise a second slit valve 135 on an opposite wall from the first valve 125. The second slit valve 135 may interface the load lock chambers 130 with the robot chambers 180.

The transfer chamber assembly 150 includes a central transfer apparatus 145 and a plurality of process stations 160. The plurality of process stations 160 are disposed around the central transfer apparatus 145, such that the plurality of process stations 160 are disposed radially outward of the central transfer apparatus 145 in the transfer chamber assembly 150.

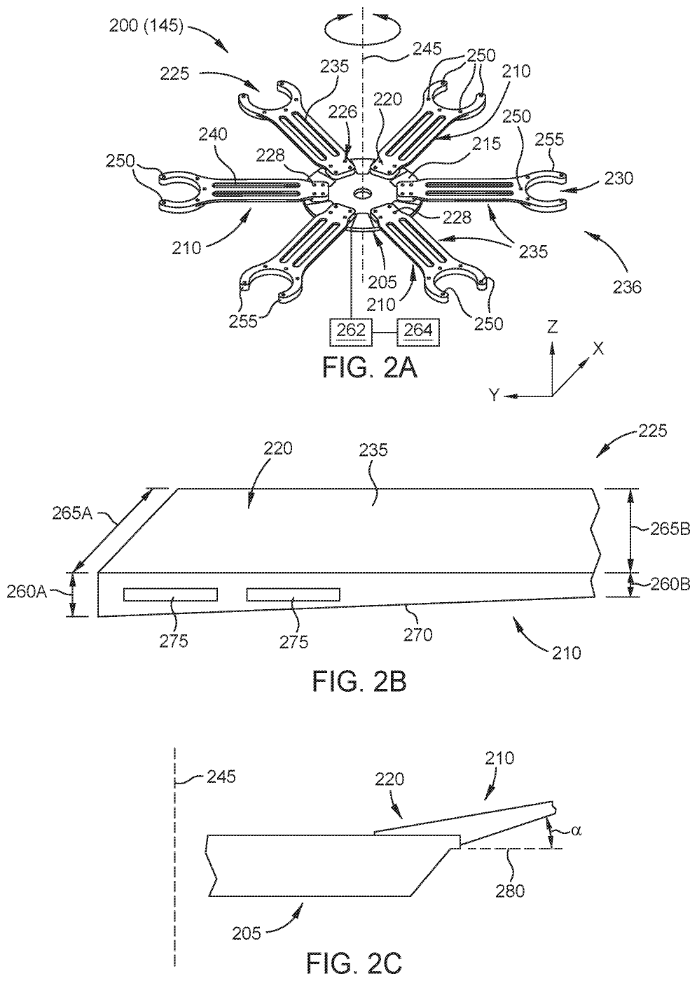

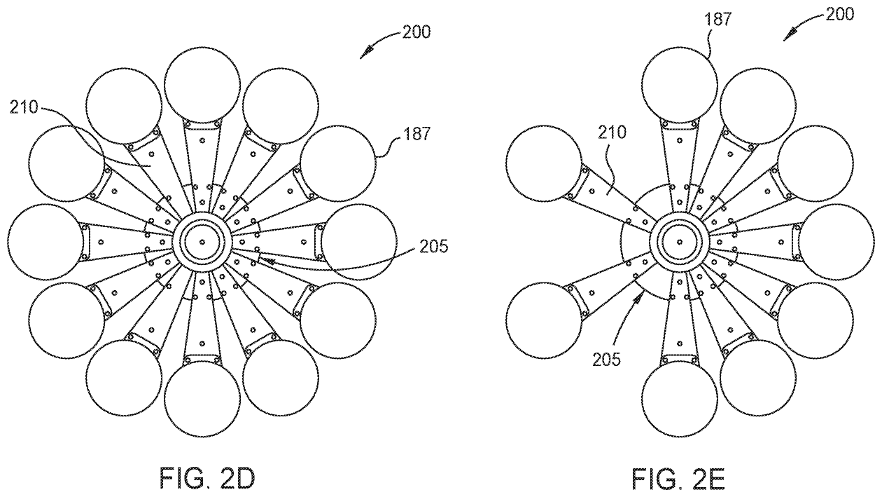

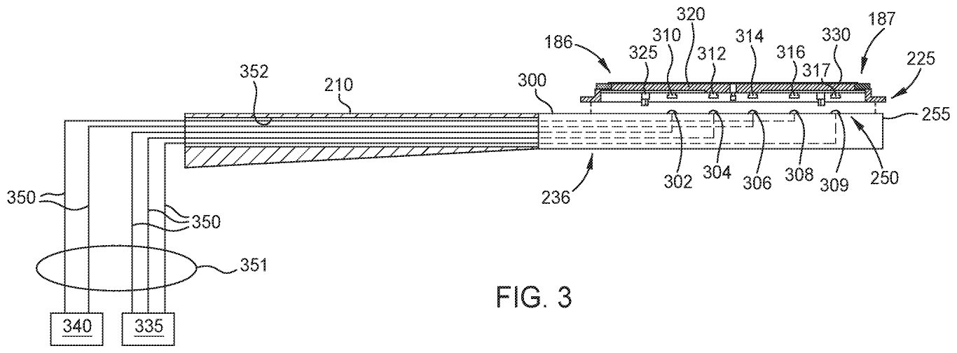

The robot chambers 180 may be on one side of the load lock chambers 130, such that the load lock chambers 130 are between the FI 120 and the robot chambers 180. The robot chambers 180 include a transfer robot 185. The transfer robot 185 may be any robot suitable to transfer one or more substrates to and from positions within a load lock chamber 130, preparation chamber 190, and process station 160 of the processing module 100. The transfer robot 185 is utilized to transfer substrates 186 to a substrate supporting component, such as a chuck assembly 187 (FIGS. 2D-2E and 3) that is temporarily connected to or positioned on a portion of the central transfer apparatus 145. The connection between the chuck assembly 187 and the central transfer apparatus 145 is described below in more detail.

The chuck assembly 187 holds a single substrate 186 and travels with the substrate 186 into each of the process stations 160 as they are moved by the central transfer apparatus 145 within the transfer chamber assembly 150. The chuck assembly 187, when disposed at one of the process stations 160 (with a substrate thereon), forms a boundary of the process station 160. The substrates 186 are mated with one of chuck assemblies 187, and the substrate 186 moves in and between the process stations 160 on that chuck assembly 187.

In some embodiments, the transfer robot 185 is configured to transport substrates from the load lock chambers 130 and into the plurality of preparation chambers 190. The transfer robot 185 removes the substrate from the load lock chamber 130, moves the substrate into the robot chamber 180, and then moves the substrate into the preparation chamber 190. The transfer robot 185 may also be configured to move substrates to the transfer chamber assembly 150. Similarly to how the substrate may be moved to the preparation chambers 190 from the load lock chambers 130 by the transfer robot 185, the substrate may also be moved from the preparation chamber 190 to the load lock chambers 130 by the transfer robot 185. The transfer robot 185 may also move substrates from the transfer chamber assembly 150 to the preparation chambers 190 or the load lock chambers 130. In some alternative embodiments, the transfer robot 185 may move a substrate from the load lock chambers 130, move the substrate into the robot chamber 180, and then move the substrate into the transfer chamber assembly 150. In this alternative embodiment, the substrate may not enter the preparation chamber 190 either before processing in the transfer chamber assembly 150 or after processing in the transfer chamber assembly 150.

The preparation chambers 190 may include a processing chamber 192, a packaging structure 194, and a cleaning chamber vacuum pump 196. The processing chamber 192 may be any one of a pre-clean chamber, an anneal chamber, or a cool down chamber, depending upon the desired process that is to be performed within this portion of the processing module 100. In some embodiments, the processing chamber 192 may be a wet clean chamber. In other embodiments, the processing chamber 192 may be a plasma clean chamber. In yet other exemplary embodiments, the processing chamber 192 may be a SiCoNi preclean or Preclean II chamber available from Applied Materials, Inc., of Santa Clara, Calif.

The packaging structure 194 may be a structural support for the processing chamber 192. The packaging structure 194 may include a sub-transfer chamber (not shown), a gas supply (not shown), and an exhaust port (not shown). The packaging structure 194 may provide the structure around the processing chamber 192 and interface the processing chamber 192 to the robot chamber 180. The cleaning chamber vacuum pump 196 is disposed adjacent to a wall of the processing chamber 192 and provides control of the pressure within the processing chamber 192. There may be one chamber vacuum pump 196 adjacent to each of the processing chambers 192. The chamber vacuum pump 196 may be configured to provide a pressure change to the processing chamber 192. In some embodiments, the chamber vacuum pump 196 is configured to increase the pressure of the processing chamber 192. In other embodiments, the chamber vacuum pump 196 is configured to decrease the pressure of the processing chamber 192, such as to create a vacuum within the processing chamber 192. In yet other embodiments, the chamber vacuum pump 196 is configured to both increase and decrease the pressure of the processing chamber 192 depending on the process being utilized within the processing module 100. The cleaning chamber vacuum pump 196 may be held in place by the packaging structure 194, such that the packaging structure 194 at least partially surrounds the cleaning chamber vacuum pump 196.

The load lock chambers 130, robot chambers 180, and preparation chambers 190 may be arranged to reduce the footprint required for the processing module 100. In one embodiment, one load lock chamber 130 is attached to a first wall of the robot chamber 180. One preparation chamber 190 may be attached to a second wall of the robot chamber 180. The first and second walls may be adjacent walls on the robot chamber 180. In some embodiments, the robot chamber 180 is roughly rectangular shaped. In other embodiments, the robot chamber 180 may be a quadrilateral. In yet other embodiments, the robot chambers 180 may be any desired shape, such as a polygon or a round shape, such as a circle. In an embodiment where the robot chambers 180 are a rectangular or quadrilateral shape, the first wall and the second wall may be adjacent walls, such that the two walls intersect each other. There may be two load lock chambers 130, two robot chambers 180, and two preparation chambers 190. The two load lock chambers 130, two robot chambers 180, and two preparation chambers 190, when arranged as described above, may form two transport assemblies. The two transport assemblies may be spaced from each other and may form mirror images of one another, such that the preparation chambers 190 are on opposite walls of their respective robot chambers 180 as shown in FIG. 1.

The transfer chamber assembly 150 is positioned adjacent to the robot chambers 180, such that the transfer chamber assembly 150 is connected to the robot chambers 180 by a slit valve (not shown). The transfer chamber assembly 150 may be attached to a third wall of the robot chambers 180. The third wall of the robot chambers 180 may be opposite the first wall of the robot chambers 180.

A chamber pump 165 may be disposed adjacent to each of the process stations 160, such that there are a plurality of chamber pumps 165 disposed around the central transfer apparatus 145. The plurality of chamber pumps 165 may also be disposed radially outward of the central transfer apparatus 145 in the transfer chamber assembly 150. There may be one chamber pump 165 for each of the process stations 160, such that one chamber pump 165 is configured to adjust the pressure within the process station 160 that they are in fluid communication with during operation. In some embodiments, there may be multiple chamber pumps 165 per process station 160. In yet other embodiments, a process station 160 may not have a chamber pump 165. In some embodiments, the chamber pumps 165 are configured to increase the pressure of the process station 160. In other embodiments, the chamber pumps 165 are configured to decrease the pressure of the process station 160, such as to create a vacuum within the process station 160. In yet other embodiments, the chamber pumps 165 are configured to both increase and decrease the pressure of the process stations 160 depending on the process being utilized within the processing module 100.

In some embodiments, there are two to twelve process stations 160 within the transfer chamber assembly 150, such as four to eight process stations 160. In some embodiments, there may be four process stations 160. In other embodiments, as shown in FIG. 1, there are six process stations 160. The number of process stations 160 may impact the total footprint of the processing module 100, the number of possible process steps capable of being performed by the processing module 100, the total fabrication cost of the processing module 100, and the throughput of the processing module 100. Utilizing six process stations 160 reduces the total footprint of the transfer chamber assembly 150, while increasing the throughput the transfer chamber assembly 150 is capable of handling. However, other quantities of process stations 160 can be used as desired by the user.

It has been found that substrate processing sequences that are used to form a repeating stacked layer configuration, wherein the stacked layer deposition processes (e.g., processes for forming multiple thin film layers) have similar chamber processing times, a significant throughput increase and improved cost of ownership (CoO) has been observed when using the one or more system configurations and methods disclosed herein. However, in process sequences used to form next generation devices, which include multilayer film stacks like On chip Inductor, optical film stacks, hard mask, patterning and memory applications, it is believed that, due to the number of layers that are to be formed and the similar processing times used to form each of the layers, a six or a twelve process station containing the processing module 250 configuration can improve substrate throughput, system footprint, and CoO over more conventional designs known in the art. In one example, it has been found that substrate processing sequences that include stacked layer deposition processes that have processing times less than 90 seconds, such as between 5 seconds and 90 seconds, in combination with the addition of lower substrate transferring overhead times achieved using the system architecture described herein, has a significant advantage over current conventional processing system designs.

The plurality of process stations 160 can be any one of PVD, CVD, ALD, etch, cleaning, heating, annealing, and/or polishing platforms. In some embodiments, the plurality of process stations 160 can all have similar platform interface and process chamber configurations. In other embodiments, the plurality of process stations 160 can include two or more types of process chamber configurations. In one exemplary embodiment, all of the plurality of process stations 160 are PVD process chambers. In another exemplary embodiment, the plurality of process stations 160 includes both PVD and CVD process chambers. Other embodiments of the makeup of the plurality of process stations may be envisioned. The plurality of process stations 160 can be altered to match the types of process chambers needed to complete a process.

The central transfer apparatus 145 may be disposed in the center of the transfer chamber assembly 150, such that the central transfer apparatus 145 is disposed around a central axis of the transfer chamber assembly 150. The central transfer apparatus 145, may be any suitable transfer device. The central transfer apparatus 145 is configured to transport substrates between each of the process stations 160. In some embodiments, the central transfer apparatus 145 is configured as a carousel system.

FIG. 2A is a perspective view of one embodiment of a central transfer apparatus 145 that includes a carousel 200. The carousel 200 may be used in the central transfer apparatus 145 of FIG. 1 according to embodiments of the disclosure described herein. The carousel 200 includes a hub 205 and a plurality of transfer arms 210. Each of the transfer arms 210 may be positionable relative to the hub 205 (e.g., in the X direction, the Y direction, and the Z direction, and combinations thereof). Each of the transfer arms 210 may also be angularly adjusted relative to the hub 205. The transfer arms 210 may be detachable from the hub 205. In some embodiments, the transfer arms 210 are mechanically coupled to the hub 205, such as by one or more fastening members 228, such as bolts or screws.

The hub 205 includes a plurality of arm fixing areas 215. The plurality of arm fixing areas 215 may be configured to allow a first (inner or a proximal) end 220 of each of the transfer arms 210 to be coupled to the hub 205. The first end 220 of the transfer arms 210 are positioned radially inward of a second (outer or distal) end 225 of the transfer arms 210. The first end 220 includes a mounting region 226 of the transfer arm 210 that is coupled to the hub 205. The second end 225 of each of the transfer arms 210 includes a component supporting region 236. In a similar embodiment, the component supporting region 236 of the second end 225 of the transfer arms 210 form a partial ring. The partial ring of the second end 225 may form more than a semicircle, such that the partial ring is greater than 180 degrees. The partial ring of the second end 225 has an opening 230 facing away from the hub 205. The opening 230 is sized to allow a portion of a robot blade or arm (not shown) to extend at least partially therein. An arm body or connecting member 235, which is part of the respective transfer arm 210, is disposed between and connects the second end 225 to the first end 220.

In some embodiments, portions of each connecting member 235 have one or more elongated openings or slots 240 formed thereon or therethrough. The slots 240 may extend from the first end 220 of the transfer arms 210 to the second end 225 of the transfer arms 210. The slots 240 are utilized to decrease the weight of the transfer arm 210 and/or reduce the heat transfer from the second end 225 to the first end 220 of the transfer arm 210.

In some embodiments, the carousel 200 is a mechanical assembly that includes at least one degree of freedom. In one configuration, the carousel 200 is capable of rotating about a rotational axis 245, but the transfer arms 210 are not equipped to move in any direction other than a rotational direction by use of a rotational motor 262. In another configuration, the carousel 200 is capable of rotating about a rotational axis 245 by use of the rotational motor 262, and moving in a direction parallel to the rotational axis 245 by use of a vertical actuator/motor 264.

At least a portion of the transfer arms 210 include a plurality of electrical interface connections 250 positioned on the component supporting region 236 of the second end 225. The electrical interface connections 250 are utilized to provide electrical power to or through the transfer arms 210 to a component that is supported on the component supporting region 236 of the transfer arm 210, such as the chuck assembly 187. The electrical interface connections 250 may be electrical contact pins extending from a surface of the component-supporting region 236 of the second end 225 of the transfer arms 210. Each of the electrical interface connections 250 are adapted contact mating electrical contacts/connections on a backside of the chuck assembly 187 (shown in FIGS. 1 and 3) and are configured to provide electrical power to electrical components (e.g., heater elements, electrostatic chucking electrodes) disposed within the chuck assembly 187 when the chuck assembly 187 is positioned thereon. The electrical interface connections 250 may be fixed or compliant. The electrical interface connections 250 may be positioned on one or both tines of a fork 255 of the second end 225 of the transfer arms 210.

The carousel 200 may be equipped with any number of transfer arms 210. FIGS. 2D and 2E illustrate examples of different transfer arm 210 configurations that can be used in a carousel 200, and are different from the transfer arm 210 configuration of the carousel 200 illustrated in FIG. 2A. In addition, the transfer arms 210 shown on the carousels 200 in FIGS. 2D and 2E include chuck assemblies 187, which is not shown in FIG. 2A and are configured to support a substrate on a substrate receiving surface formed thereon (i.e., top surface of the chuck assemblies 187).

The number of transfer arms 210 may be an even number or odd number. For example, the carousel 200 may have 5, 6, 7, 8, 9, 10, 11, 12, or any number of transfer arms 210 that is higher or lower. An example of a 12 transfer arm 210 configuration is illustrated in FIG. 2D. The number of transfer arms 210 may equal the number of process stations 160 (shown in FIG. 1). In some embodiments, there may be more transfer arms 210 in one sector of the carousel 200 than another sector such that the carousel 200 is differently loaded (such as 3 transfer arms 210 in one sector that spans about half the circumference about the rotational axis 245 and 6 transfer arms 210 on the other side of the rotational axis 245 as shown in FIG. 2E). In some embodiments, one or more of the transfer arms 210 illustrated in FIGS. 2D and 2E may be configured to transport a shutter disk (not shown) instead of a chuck assembly 187. A shutter disk is typically a wafer (i.e., substrate) sized plate or disk that is typically used to take the place of a wafer during a PVD pasting operation used to clean the surface of a PVD target. Referring to FIG. 2D, for example, one of the transfer arms 210 between two other transfer arms 210 (i.e., each of the odd numbered transfer arms) may be configured to support and transport a shutter disk, while all of the other arms (i.e., each of the even numbered transfer arms) are configured to transfer the chuck assembly 187. The number of transfer arms 210 configured to transport shutter disks and chuck assemblies 187 may equal the number of process stations 160 (shown in FIG. 1). For example, if there are six process stations 160, there are twelve transfer arms 210 (6 for transporting a chuck assembly 187 and 6 for transporting a shutter disk). The transfer arms 210 for holding a chuck assembly 187 may alternate with the transfer arms 210 for holding a shutter disk.

FIG. 2B is a schematic perspective view of a portion of one of the transfer arms 210 of the carousel 200 of FIG. 2A according to one embodiment. The transfer arm 210 according to this embodiment includes a non-uniform geometry in order to improve structural stiffness, reduce mass and reduce heat transfer between the second end 225 and the first end 220. One will note that these design goals each have competing effects and thus must be balanced to achieve a desirable design. For example, increasing a transfer arm's stiffness will undesirably increase its mass (i.e., increase rotational inertia) and undesirably increase the ability of the transfer arm to conduct heat between the first end 220 and the second end 225.

In some embodiments, the transfer arm 210 includes the first end 220 having a first thickness 260A and the second end 225 includes a second thickness 260B. The first thickness 260A is greater than the second thickness 260B. The first end 220 of the transfer arm 210 also includes a first width 265A and the second end 225 includes a second width 265B. The first width 265A is less than the second width 265B. Additionally, to reduce the transfer arm's mass and ability to conduct heat, sides 270 of the transfer arm 210 include one or more elongated openings or slots 275 formed thereon or therethrough. The slots 275 are similar to the slots 240 formed in major surfaces of the connecting member 235 described above and are utilized to decrease weight or heat transfer through the transfer arms 210. The percentage of surface area occupied by the slots 275 relative to the surface area of each side 270 of the transfer arm 210 is about 20% to about 40% in some embodiments. The slots 275 formed in the sides 270 of the transfer arm 210 mimic structural “I beams” or “H beams” which minimizes deflection of the transfer arm 210 under load with same material thickness. The number of slots 275 per transfer arm 210 may be about two to three slots 275 per each side 270 in order to reduce manufacturing costs while maximizing structural integrity and/or heat transfer.

FIG. 2C is a schematic side view of a portion of the hub 205 and a transfer arm 210 mounted thereto. In this embodiment, the transfer arm 210 is angled at an angle α relative to the central rotational axis 245 of the carousel 200. The angle α may be about 5 degrees to about 15 degrees relative to a horizontal plane 280 that is orthogonal to the rotational axis 245. The angle α of the transfer arms 210 is utilized to minimize droop due to weight of the chuck assemblies 187 (or shutter disks) on the second end 225.

FIG. 3 is a schematic sectional side view of a portion of one of the transfer arms 210 of the carousel 200 of FIG. 2A. The electrical interface connections 250 are shown on the fork 255 of the second end 225 of the transfer arm 210. Also shown is a chuck assembly 187 in a spaced-apart relation to a disk receiving surface 300 of the component supporting region 236 at the fork 255. A substrate 186 is shown attached to the chuck assembly 187, which is supported on the component supporting region 236 of the transfer arm 210.

Each of the electrical interface connections 250 may be shaped as a protruding member or pin shown as 302, 304, 306, 308, and 309. When the chuck assembly 187 is contacting the disk receiving surface 300 during operation, each of the pins 302, 304, 306, 308 and 309 are configured to align and mate with or contact electrical contacts formed in or on the chuck assembly 187, shown as mating connectors 310, 312, 314, 316 and 317. For example, a first pin 302 contacts the mating connector 310, a second pin 304 contacts the mating connector 312, a third pin 306 contacts the mating connector 314, a fourth pin 308 contacts the mating connector 316, and a fifth pin 309 contacts the mating connector 317.

Each of the electrical interface connections 250 are configured to provide electrical power to electrical components within the chuck assembly 187 while the chuck assembly 187 and substrate 186 are positioned on the transfer arm 210. For example, the first pin 302 and the second pin 304 are coupled to a heater power source 335, through a rotational coupling assembly 351 (e.g., slip ring), that provides alternating current (AC) to a heater 320 formed in the chuck assembly 187. In another example, the third pin 306 and the fourth pin 308 are coupled to a chucking power source 340, through the rotational coupling assembly 351, that provides direct current (DC) power to an electrostatic chuck 325 formed in the chuck assembly 187. Conductors or wires 350 are routed through each transfer arm 210, which is positioned within the vacuum region of the chamber assembly 150, to the pins 302, 304, 306, 308 and 309. The wires 350 are routed through an opening or through-hole 352 formed in the transfer arm 210. The wires 350 may alternately or additionally be are routed through a channel (not shown) formed in a surface of the transfer arm 210. For example, three wires 350 are coupled to the heater power source 335 and two wires 350 are coupled to the chucking power source 340 in each transfer arm 210. The fifth pin 309 of the electrical interface connections 250, is a neutral or return for the AC power provided by the heater power source 335. The heater 320 may be a zoned heater, for example having an inner and outer zone. The heater 320 and the electrostatic chuck 325 are shown schematically within an upper body 330 of the chuck assembly 187.

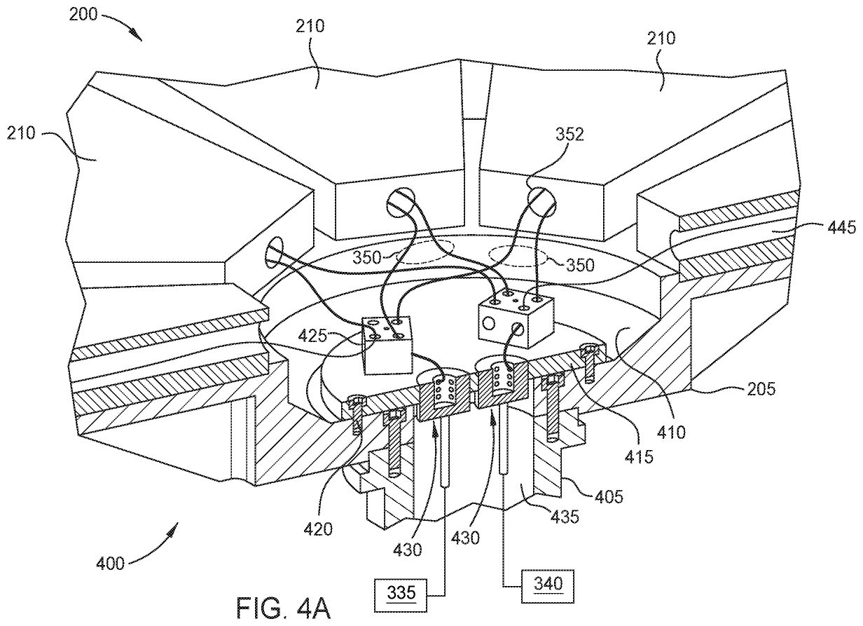

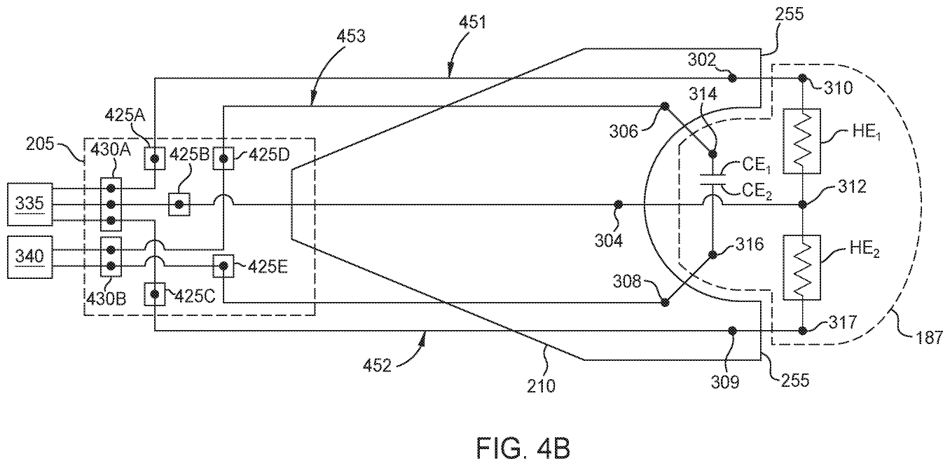

FIG. 4A is a schematic sectional perspective view of a shaft assembly 400 according to one embodiment of the carousel 200. The shaft assembly 400 includes a hollow shaft 405 that is coupled to the hub 205. Each of the plurality of transfer arms 210 is coupled to the hub 205. The hub 205 includes a recessed portion 410 formed in a center thereof. A central cap 415 of the hub 205 is disposed in the recessed portion 410. The central cap 415 is utilized to fix the hub 205 to the hollow shaft 405, for example, using fasteners 420.

The central cap 415 includes a plurality of terminal blocks 425 mounted thereon. Each of the terminal blocks 425 may be made of a ceramic material or a polymer, such as polyether ether ketone (PEEK). Each of the terminal blocks 425 provide electrical power from a plurality of sealed feed-throughs 430 formed between the hollow shaft 405 and the central cap 415. The sealed feed-throughs 430 may be a vacuum-tight electrical feed-through that is configured to transfer power from an interior volume 435 of the hollow shaft 405, which is at ambient or atmospheric pressures while the transfer arms 210 and upper portion of the hub 205 and other portions connected thereto are positioned within a transfer region that is at a negative pressure during use.

The feed-throughs 430 are separately coupled to the heater power source 335 (AC) and the chucking power source 340 (DC). Typically, one of each power source is operably coupled to each transfer arm 210. Wires are provided to the terminal blocks 425 from the feed-through 430 to the terminal blocks 425, and wires 350 are provided from the terminal blocks 425 on or through each of the plurality of transfer arms 210 to supply power to the electrical interface connections 250 (shown in FIGS. 2A and 3). In one embodiment, wires 350 from the terminal blocks 425 are routed via through-holes 352 formed in each of the plurality of transfer arms 210.

FIG. 4B illustrates a schematic representation of one embodiment of an electrical circuit formed when a chuck assembly 187 is positioned on a transfer arm 210 of the carousel 200. More specifically, FIG. 4B shows the electrical connections that are formed between the pins 302, 304, 306, 308 and 309 of the transfer arm 210 with the mating connectors 310, 312, 314, 316 and 317 of the chuck assembly 187, respectively. In one embodiment, a first circuit 451, which is used to generate heat in the chuck assembly 187, is formed due to the connection of a first terminal (e.g., positive terminal) of the heater power source 335 to a first terminal of the first feed-through 430A that is connected to a first terminal block 425A that is electrically coupled to pin 302 that is in electrical contact with the mating connector 310 that is electrically coupled to a first heating element HE₁ that is electrically connected the mating connector 312 that is in electrical contact with the pin 304 that is connected to a second terminal block 425B that is coupled to a second terminal in the first feed-through 430A that is coupled to the second terminal (e.g., negative terminal) of the heater power source 335 to complete the circuit. Similarly, a second circuit 452, which can also be used to generate heat in the chuck assembly 187, is formed due to the connection of a third terminal (e.g., positive terminal) of the heater power source 335 to a third terminal of the first feed-through 430A that is connected to a third terminal block 425C that is electrically coupled to pin 309 that is in electrical contact with the mating connector 317 that is electrically coupled to a second heating element HE₂ that is electrically connected the mating connector 312 that is in electrical contact with the pin 304 that is connected to a second terminal block 425B that is coupled to a second terminal in the first feed-through 430A that is coupled to the second terminal (e.g., negative terminal) of the heater power source 335 to complete the circuit.

In some embodiments, as illustrated in FIG. 4B, the chuck assembly 187 includes a pair of chucking electrodes CE₁ and CE₂ that are used to create an electrostatic chucking force due to the application of a high voltage, which is applied by the chucking power source 340, to the chucking electrodes CE₁ and CE₂ that are disposed within a dielectric body (e.g., aluminum nitride) of the chuck assembly 187. In one embodiment, a third circuit 453, which is used to generate a bias between the chucking electrodes CE₁ and CE₂ within the chuck assembly 187, is formed due to the connection of a first terminal (e.g., positive terminal) of the chucking power source 340 to a first terminal of the second feed-through 430B that is connected to a fourth terminal block 425D that is electrically coupled to pin 306 that is in electrical contact with the mating connector 314 that is electrically coupled to the first electrode CE₁ that is positioned adjacent to the second electrode CE₂ that is electrically connected the mating connector 316 that is in electrical contact with the pin 308 that is connected to a fifth terminal block 425E that is coupled to a second terminal in the second feed-through 430B that is coupled to the second terminal (e.g., negative terminal) of the chucking power source 340 to complete the biasing circuit.

Referring to FIG. 4A, each of the terminal blocks 425 provide a common connection point for the same portions of the electrical circuit illustrated in FIG. 4B that are provided in each of transfer arms 210 within the carousel. Thus, the terminal blocks 425A-425C and terminal blocks 425D-425E are each used to reduce the number of wires that would be required to form the same electrical circuits in each of the transfer arms 210 of the carousel. In one example, a carousel that included six transfer arms 210 would require 30 separate wires and typically greater than two feed-throughs 430 to form the electrical circuits 451, 452 and 453 in each of the six transfer arms 210, if the configuration shown in FIG. 4B were not used. However, using the central terminal block configuration illustrated in FIG. 4B, only five wires and two simplified feed-throughs 430 are needed to connect the power sources 335 and 340 to the portions of the electrical circuits 451, 452 and 453 within each of the transfer arms 210 of a carousel that contained six, twelve, or even eighteen or more transfer arms 210. In one configuration, a single heater power source 335 is connected to the terminal blocks 425A-425C, as shown in FIG. 4B, which are configured to then distribute the power provided from the heater power source 335 to each of the portions of the electrical circuits 451 and 452 within each of the transfer arms 210 (i.e., portions of the electrical circuits 451 within the transfer arms are all connected in parallel, and portions of the electrical circuits 452 within the transfer arms are all connected in parallel). Additionally, or in another configuration, a single chucking power source 340 is connected to the terminal blocks 425D-425E, as shown in FIG. 4B, which are configured to then distribute the power provided from the chucking power source 340 to each of the portions of the electrical circuits 453 that are disposed within each of the transfer arms 210 (i.e., electrical circuits 453 are all connected in parallel).

In some embodiments, a separate power supply is configured to separately control the power delivered to each portion of the electrical circuits 451, 452 and 453 formed in each of the transfer arms 210 in the carousel. In one example, a six transfer arm 210 carousel design includes six heater power sources 335 and six chucking power sources 340 that are each dedicated to a portion of the electrical circuit formed in each transfer arm 210. However, the number of terminal blocks that would be required to allow each portion of the electrical circuits 451, 452 and 453 to controlled independently can be less than a more conventional 30 terminal block design, since the second terminal block 425B and fifth terminal block 425C can each be used as a common reference point in each of the electrical circuits 451, 452 and 453 in each of the transfer arms 210. Thus, in one configuration, only 20 terminal blocks (i.e., six 425A's, six 425C's, six 425D's, one 425B and one 425E) and feed-through connection points are required, since the second terminal in each of the heater power sources 335 are connected to a single second terminal block 425B and the second terminal in each of the chucking power sources 340 are connected to a single fifth terminal block 425.

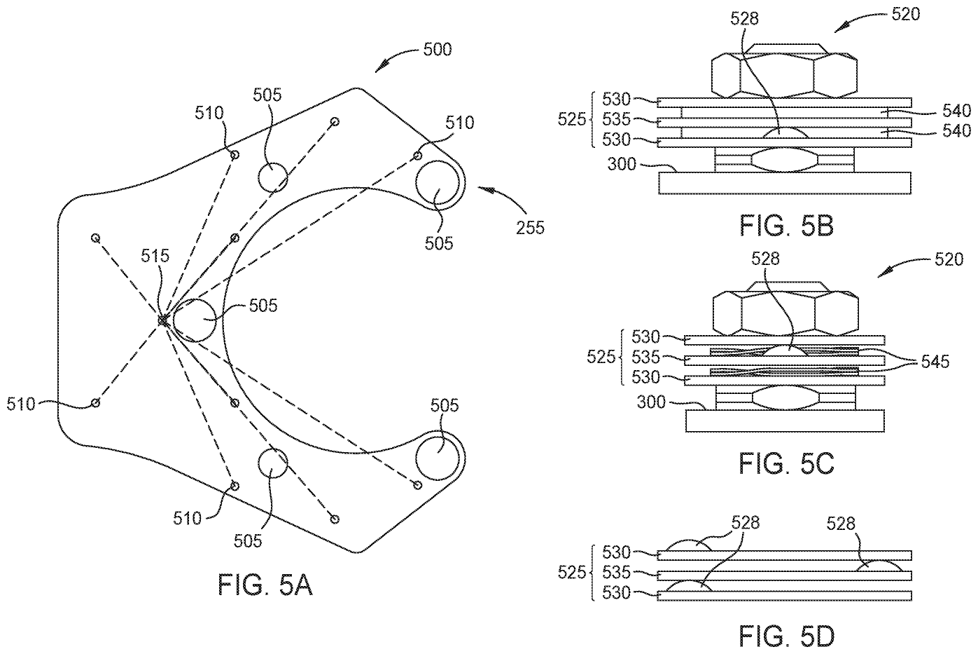

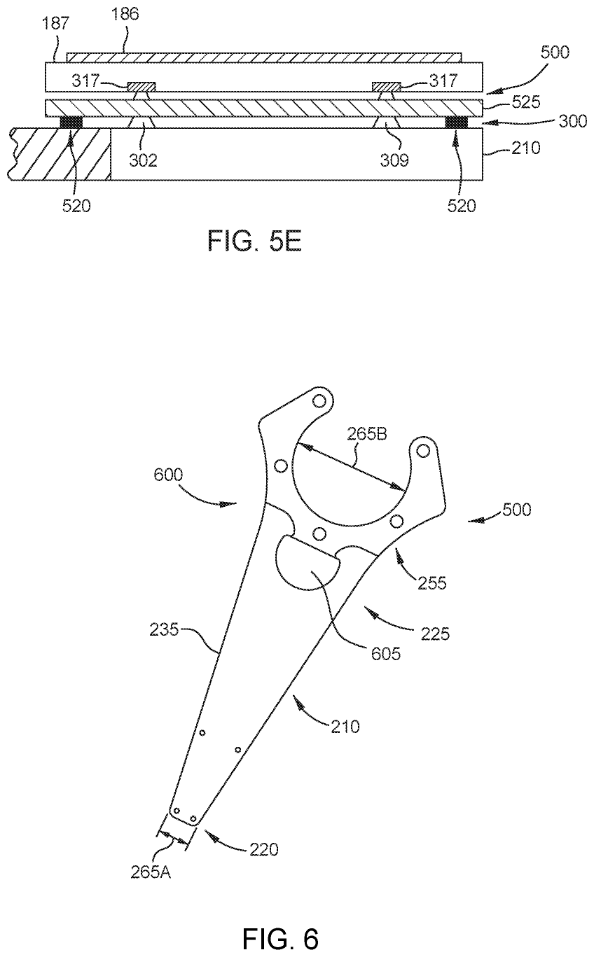

FIG. 5A is a top plan view of a heat shield assembly 500 that may be utilized over a portion of the component supporting region 236 of a transfer arm 210 as described herein. FIGS. 5B-5D are side views of portions of the heat shield assembly 500 shown in FIG. 5A. FIG. 5E is a side sectional view of the heat shield assembly 500, the chuck assembly 187, and a portion of the transfer arm 210. The heat shield assembly 500 is utilized to minimize radiant and conductive heat transfer provided from the chuck assembly 187. As illustrated in FIG. 5E, the heat shield assembly 500 is disposed over the transfer arm 210 and thus is positioned between the transfer arm 210 and a chuck assembly 187, when the chuck assembly 187 is positioned on the transfer arm 210. The heat shield assembly 500 will significantly reduce the heat load provided transfer arm 210 and hub 205 when the chuck assembly 187 positioned on the transfer arm 210 for extended periods of time and the chuck assembly 187 is maintained a moderate to high processing temperatures, such as temperatures greater than 200° C., greater than 400° C., or even greater than 500° C.

The heat shield assembly 500 includes a plurality of first openings 505 that are sized to allow passage of the pins 302, 304, 306 and 308 (shown in FIGS. 2A and 3) as well as a pin (e.g., 309) for a neutral or return electrical interface. The heat shield assembly 500 also includes a plurality of second openings shown as peripheral openings 510 that are formed radially outward of a central opening 515. Each of the plurality of peripheral openings 510 as well as the central opening 515 receives a fastener 520 (shown in FIGS. 5B and 5C).

As shown in FIGS. 5B-5D, the heat shield assembly 500 comprises a body 525 that is coupled to the disk receiving surface 300 of the fork 255 (shown in FIG. 2A) of the transfer arms 210. The body 525 includes a plurality of spaced-apart plates shown as outer plates 530 and an inner plate 535. The outer plates 530 and the inner plate 535 include a plurality of protrusions 528 (shown in FIG. 5D) configured to maintain spacing therebetween while minimizing thermal conduction and blocking thermal radiation to the component supporting region 236 of the transfer arm 210. Each of the outer plates 530 and inner plate 535 comprise a thermally insulative and/or optically reflective material, such as a ceramic material. As shown in FIG. 5C, the body 525 attaches to the disk receiving surface 300 of the fork 255 by the fastener 520 at the central opening 515 (shown in FIG. 5A). Likewise, as shown in FIG. 5B, the body 525 attaches to the disk receiving surface 300 of the fork 255 by the fastener 520 at points corresponding to the peripheral openings 510 (shown in FIG. 5A). FIG. 5E also shows more details of the coupling arrangement of the chuck assembly 187, the heat shield assembly 500 and the transfer arm 210.

The difference between the attachment interfaces shown in FIGS. 5B and 5C may be based on thermal expansion of the heat shield assembly 500 relative to the transfer arm 210. For example, the central opening 515 is configured as the thermal center of the body 525. As such, a rigid connection (relative to the attachment interface shown in FIG. 5C) is utilized, such as flat, rigid washers 540 between the outer plates 530 and the inner plate 535. Since the central opening 515 is considered the thermal center of the heat shield assembly 500, little or no thermal expansion occurs at that point. However, thermal expansion is expected to occur at points radially positioned from the central opening 515, such as at the positions of the peripheral openings 510. In contrast to the interface shown in FIG. 5B, the interface shown in FIG. 5C includes flexible washers 545 which allow movement of the portions of the body 525 in response to thermal forces (e.g., thermal expansion) created by temperature differences between the chuck assembly 187 and the transfer arms 210. While not shown, one or more of the peripheral openings 510 may be slotted to allow movement between the heat shield assembly 500 and the disk receiving surface 300 of the fork 255.

FIG. 6 is a plan view of a transfer arm assembly 600 according to an embodiment. The transfer arm assembly 600 includes the transfer arm 210 coupled with the heat shield assembly 500 on the fork 255 shown in FIG. 5A. The tapered width of the connecting member 235 is clearly shown in FIG. 6 referenced by the first width 265A and the second width 265B. In this embodiment, the connecting member 235 includes a lightening hole 605 at the second end 225 thereof. The lightening hole 605 is similar to the slots 275 shown in FIG. 2A and is utilized to decrease weight and/or to reduce heat conduction of the transfer arm 210.

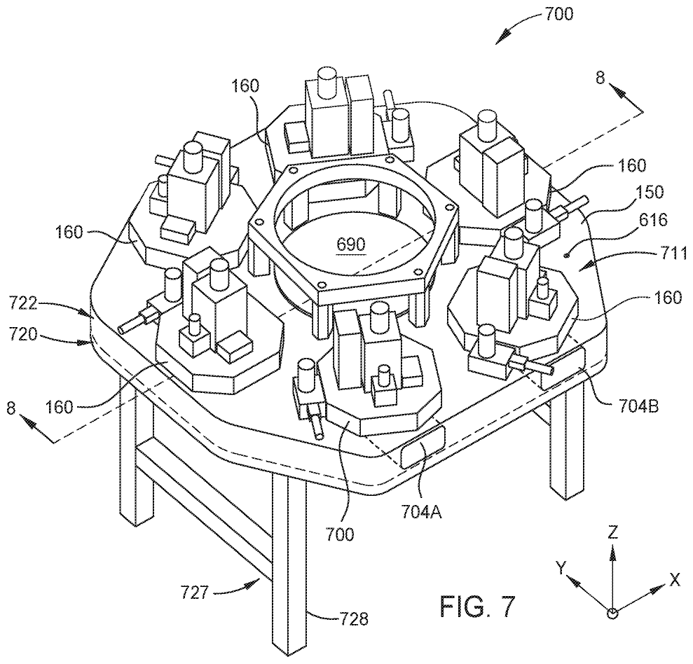

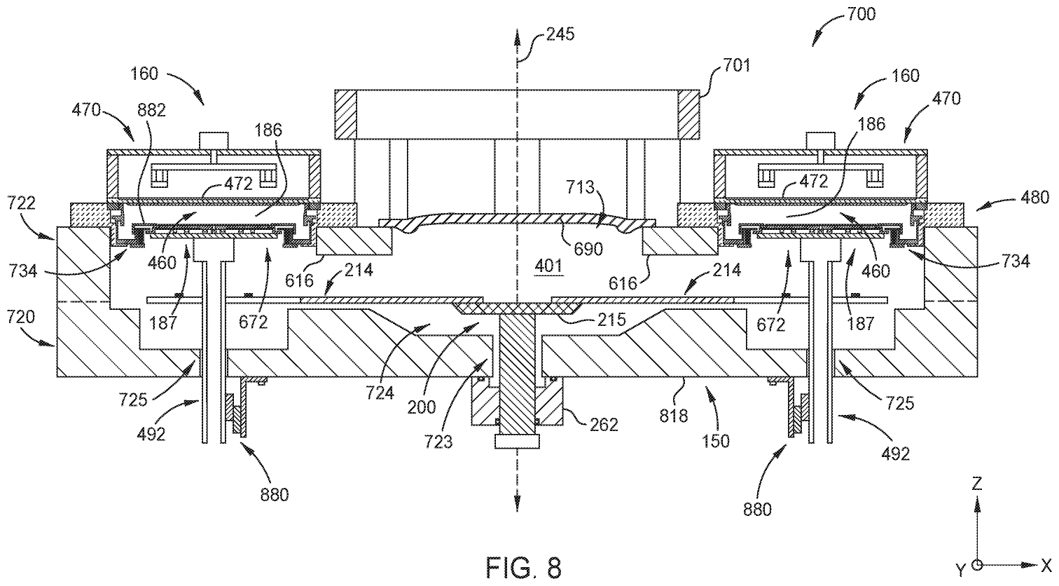

FIG. 7 is an isometric view of a processing module 700 according to another embodiment. The processing module 700 may be utilized as the processing module 100 in the tool as depicted in FIG. 1. The processing module 700 includes a transfer chamber assembly 150, according to one or more embodiments. FIG. 8 is a side cross-sectional view of the processing module 700 formed along the section line 8-8 illustrated in FIG. 7, according to one or more embodiments.

Referring to FIGS. 7 and 8, the processing module 700 includes a lower monolith 720 forming the lower portion or base of the processing module 700, and an upper monolith 722 that is sealed thereto and supported thereon. In some embodiments, lower monolith 720 and the upper monolith 722 are welded, brazed or fused together by some desirable means to form a vacuum tight joint at the interface between the lower monolith 720 and the upper monolith 722. In some embodiments, the lower monolith 720 has a generally plate like structure that has seven side facets. As shown in FIG. 8, the lower monolith 720 includes a lower wall 818 that includes a central opening 723 disposed within a central recess 724 positioned within a central region, and a plurality of lower process station openings 725 (two shown in FIG. 8), each corresponding to the location of a process station 160. A plurality of pedestal assemblies 492, two of which are shown in FIG. 8, extend through and downwardly from the lower wall 818. A lower supporting structure 727, which includes a support frame 728, is used to support the lower monolith 720 and the upper monolith 722 and position the processing module 700 at a desired vertical position above a floor (not shown).

In FIG. 8, the carousel 200 as described herein is positioned in a transfer region 401 of the upper monolith 722 and the lower monolith 720. Substrates 186, positioned on substrate supports 672 of the pedestal assemblies 492, are processed in a respective processing region 460 of each process station 160. In one example, the processing region 460 includes a target 472 wherein a material of the target 472 is sputtered onto the substrates 186 forming a film thereon.

As described above, the carousel 200 rotates about the rotational axis 245 with the chuck assembly 187 thereon. Substrates 186 are transferred to the chuck assembly 187 (in the position shown in FIG. 3) using the transfer robot 185 of the robot chamber 180 (shown in FIG. 1) through openings 704A or 704B (shown in FIG. 7). Each of the pedestal assemblies 492 are coupled to a vertical actuator 880 that lifts the respective chuck assembly 187 from the component supporting region 236 in the Z direction to a position as shown in FIG. 8. A deposition ring 882 seals a periphery of the chuck assembly 187 in this position and forms the processing region 460. After deposition in the processing region 460, the chuck assembly 187 is lowered using the vertical actuator 880 onto the component supporting region 236 of the carousel 200. Thereafter, processed substrates are transferred out of the transfer region 401 using the transfer robot 185.

In some embodiments, the upper monolith 722 has a generally plate like structure that has eight side facets that match those of the lower monolith 720. An upper main portion 711, which includes the chamber upper wall 616, includes a central opening 713 disposed within a central region, and a plurality of upper process station openings 734, each corresponding to the location where a process kit assembly 480 and a source assembly 470 of the process station 160 are positioned. A removable central cover 690 extends over the central opening 713. The removable central cover 690 includes a seal (not shown) that prevents the external environmental gases from leaking into the transfer region 401 when the transfer region 401 is maintained in a vacuum state by the vacuum pump (shown in FIG. 1).

While the foregoing is directed to embodiments of the present disclosure, other and further embodiments of the disclosure may be devised without departing from the basic scope thereof, and the scope thereof is determined by the claims that follow.

What is claimed is:

1. A transfer apparatus for use in a multiple processing region system, comprising:
a carousel that includes a hub having a plurality of transfer arms extending therefrom, wherein each of the transfer arms include:
a first end coupled to the hub and a second end, the second end comprising a component supporting region; and
a plurality of electrical interface connections distributed about the component supporting region.

2. The transfer apparatus of claim 1, wherein the first end includes a first thickness and the second end includes a second thickness.

3. The transfer apparatus of claim 2, wherein the first thickness is greater than the second thickness.

4. The transfer apparatus of claim 1, wherein the first end includes a first width and the second end includes a second width.

5. The transfer apparatus of claim 4, wherein second width is greater than the first width.

6. The transfer apparatus of claim 1, wherein each of the plurality of transfer arms tapers in width from the first end to the second end.

7. The transfer apparatus of claim 1, wherein each of the plurality of transfer arms tapers in thickness from the first end to the second end.

8. The transfer apparatus of claim 1, further comprising a heat shield assembly coupled to the component supporting region.

9. The transfer apparatus of claim 1, wherein each of the plurality of transfer arms includes a through-hole formed therein for receiving a plurality of electrical wires positioned between the hub and the electrical interface connections.

10. A transfer apparatus, comprising:
a carousel that includes a hub having a plurality of transfer arms extending therefrom, wherein each of the transfer arms include:
a first end and a second end; and
a plurality of electrical interface connections distributed about the second end and protruding from a surface thereof, wherein each of the plurality of transfer arms includes a feature formed therein for receiving a plurality of electrical wires positioned between the hub and the electrical interface connections.

11. The transfer apparatus of claim 10, wherein the hub includes a recessed portion and a central cap.

12. The transfer apparatus of claim 11, wherein the central cap includes one or more vacuum-electrical feed-throughs.

13. The transfer apparatus of claim 11, wherein the central cap includes a plurality of terminal blocks for distributing power to each of the electrical interface connections on each of the transfer arms.

14. The transfer apparatus of claim 10, wherein each of the plurality of transfer arms tapers in width from the first end to the second end, and the second end comprises a fork.

15. The transfer apparatus of claim 10, wherein each of the plurality of transfer arms tapers in thickness from the first end to the second end.

16. An apparatus for substrate processing, comprising:
a plurality of processing chambers coupled to a central transfer chamber, wherein the central transfer chamber comprises:
a carousel that comprises:
a hub having a plurality of transfer arms extending therefrom at an angle relative to a rotational axis of the carousel, wherein each of the transfer arms include a first end and a second end, and
a plurality of electrical interface connections distributed about the second end.

17. The transfer apparatus of claim 16, wherein the hub includes a recessed portion and a central cap.

18. The transfer apparatus of claim 17, wherein the central cap includes one or more vacuum-electrical feed-throughs.

19. The transfer apparatus of claim 17, wherein the central cap includes a plurality of terminal blocks for distributing power to each of the electrical interface connections on each of the transfer arms.

20. The transfer apparatus of claim 16, wherein each of the plurality of transfer arms tapers in width and/or length from the first end to the second end.
